(19) United States
(12) Patent Application Publication
(10) Pub. No.: US 2025/0089470 A1
(43) Pub. Date: Mar. 13, 2025

(54) DISPLAY DEVICE

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 18/830,831

(22) Filed: Sep. 11, 2024

(30) Foreign Application Priority Data
Sep. 13, 2023 (JP) 2023-148307

(51) Int. Cl. H10K 59/122; H10K 59/131

(52) U.S. Cl. CPC H10K 59/122; H10K 59/131

(57) ABSTRACT

According to one embodiment, a display device includes first and second lower electrodes having first and second end portions, a rib layer which has first and second pixel apertures and covers the end portions, a partition which includes a lower portion between the pixel apertures, and an upper portion having an end portion protruding from a side surface of the lower portion, first and second organic layers which are in contact with the lower electrodes through the pixel apertures, and first and second upper electrodes which cover the organic layers. The first end portion overlaps the lower portion in plan view. The second end portion does not overlap the lower portion in plan view.

### CROSS-REFERENCE TO RELATED APPLICATION

This application is based upon and claims the benefit of priority from Japanese Patent Application No. 2023-148307, filed Sep. 13, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. In this type of display devices, a technique which can improve the yield and display quality is required.

### BRIEF DESCRIPTION OF THE DRAWINGS

FIG. 1 is a diagram showing a configuration example of a display device according to a first embodiment.

FIG. 2 is a schematic plan view showing an example of the layout of subpixels according to the first embodiment.

FIG. 3 is a schematic cross-sectional view of the display device along the A-B line of FIG. 2.

FIG. 4 is a schematic cross-sectional view of the display device along the C-D line of FIG. 2.

FIG. 5 is a diagram showing an example of a layer structure which could be applied to each organic layer.

FIG. 6 is a schematic enlarged plan view of the subpixels shown in FIG. 2.

FIG. 7 is a schematic enlarged cross-sectional view of the lower electrodes, rib layer and partition shown on the left side of FIG. 3.

FIG. 8 is a schematic enlarged cross-sectional view of the vicinity of the both end portions of the lower electrode shown in FIG. 3.

FIG. 9 is a schematic cross-sectional view of the configuration of a comparative example.

FIG. 10 is a schematic cross-sectional view of the configuration of another comparative example.

FIG. 11 is a schematic cross-sectional view of a display device according to a second embodiment.

FIG. 12 is a schematic enlarged plan view of subpixels according to a third embodiment.

FIG. 13 is a schematic enlarged plan view of subpixels according to a fourth embodiment.

FIG. 14 is a schematic enlarged plan view of subpixels according to a fifth embodiment.

FIG. 15 is a schematic enlarged plan view of subpixels according to a sixth embodiment.

### DETAILED DESCRIPTION

In general, according to one embodiment, a display device comprises a first lower electrode having a first end portion, a second lower electrode having a second end portion spaced apart from the first end portion, a rib layer which has a first pixel aperture overlapping the first lower electrode and a second pixel aperture overlapping the second lower electrode, and covers the first end portion and the second end portion, a partition which includes a lower portion located between the first pixel aperture and the second pixel aperture and provided above the rib layer, and an upper portion having an end portion protruding from a side surface of the lower portion, a first organic layer which is in contact with the first lower electrode through the first pixel aperture and emits light based on application of voltage, and a second organic layer which is in contact with the second lower electrode through the second pixel aperture and emits light based on application of voltage, a first upper electrode which covers the first organic layer, and a second upper electrode which covers the second organic layer. Further, the first end portion overlaps the lower portion in plan view. The second end portion does not overlap the lower portion in plan view.

According to another aspect of the embodiment, a display device comprises a lower electrode having a first end portion and a second end portion, a rib layer which has a pixel aperture overlapping the lower electrode and covers the first end portion and the second end portion, a partition which includes a lower portion provided above the rib layer and an upper portion having an end portion protruding from a side surface of the lower portion, and surrounds the pixel aperture, an organic layer which is in contact with the lower electrode through the pixel aperture, and emits light based on application of voltage, and an upper electrode which covers the organic layer. Further, the first end portion overlaps the lower portion in plan view. The second end portion does not overlap the lower portion in plan view.

These configurations can realize the improvement of the yield of a display device or the improvement of display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

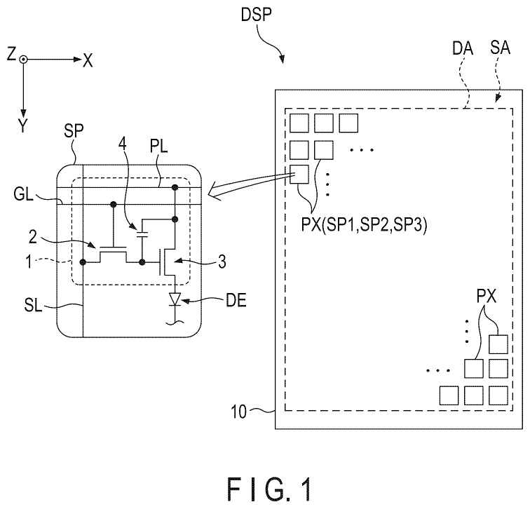

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel PX includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

A plurality of scanning lines GL which supply scanning signals to the pixel circuits 1 of subpixels SP, a plurality of signal lines SL which supply video signals to the pixel circuits 1 of subpixels SP and a plurality of power lines PL are provided in the display area DA. In the example of FIG. 1, the scanning lines GL and the power lines PL extend in the X-direction, and the signal lines SL extend in the Y-direction.

The gate electrode of the pixel switch 2 is connected to the scanning line GL. The source electrode of the pixel switch 2 is connected to the signal line SL. The drain electrode of the pixel switch 2 is connected to the gate electrode of the drive transistor 3 and the capacitor 4. The source electrode of the drive transistor 3 is connected to the power line PL and the capacitor 4. The drain electrode of the drive transistor 3 is connected to the display element DE.

It should be noted that the configuration of the pixel circuit 1 is not limited to the example shown in the figure. For example, the pixel circuit 1 may comprise more thin-film transistors and capacitors.

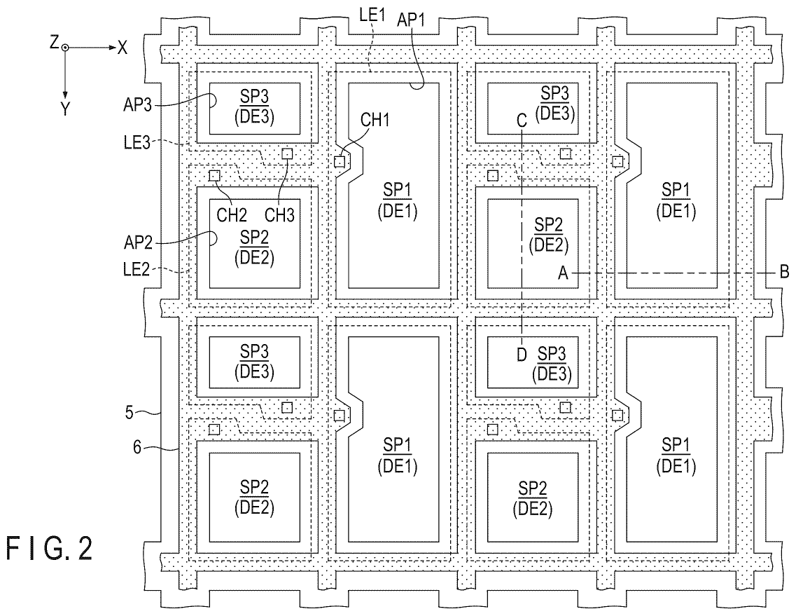

FIG. 2 is a schematic plan view showing an example of the layout of subpixels SP1, SP2 and SP3. In the example of FIG. 2, a column in which subpixels SP2 and SP3 are alternately provided in the Y-direction and a column in which a plurality of subpixels SP1 are repeatedly provided in the Y-direction are formed. These columns are alternately arranged in the X-direction.

For example, the widths of subpixels SP1, SP2 and SP3 in the X-direction are equal to each other. The width of each subpixel SP1 in the Y-direction is equal to the total width of subpixels SP2 and SP3 in the Y-direction.

The layout of subpixels SP1, SP2 and SP3 or the size of subpixel SP1, SP2 or SP3 is not limited to the example of FIG. 2. As another example, subpixels SP1, SP2 and SP3 may be arranged in the X-direction. The sizes of at least two of subpixels SP1, SP2 and SP3 may be equal to each other.

A rib layer 5 is provided in the display area DA. The rib layer 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

A partition 6 is provided in the display area DA. The partition 6 is located above the rib layer 5 and overlaps the rib layer 5 as a whole. In the example of FIG. 2, the partition 6 has a planar shape similar to that of the rib layer 5. In other words, the partition 6 has an aperture in each of subpixels SP1, SP2 and SP3. From another viewpoint, the partition 6 has a grating shape as seen in plan view and surrounds each of the pixel apertures AP1, AP2 and AP3.

Subpixel SP1 comprises a display element DE1 which includes a lower electrode LE1 overlapping the pixel aperture AP1. Subpixel SP2 comprises a display element DE2 which includes a lower electrode LE2 overlapping the pixel aperture AP2. Subpixel SP3 comprises a display element DE3 which includes a lower electrode LE3 overlapping the pixel aperture AP3. The pixel circuits 1 of subpixels SP1, SP2 and SP3 are provided under the lower electrodes LE1, LE2 and LE3, respectively. The lower electrode LE1 is connected to the pixel circuit 1 of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

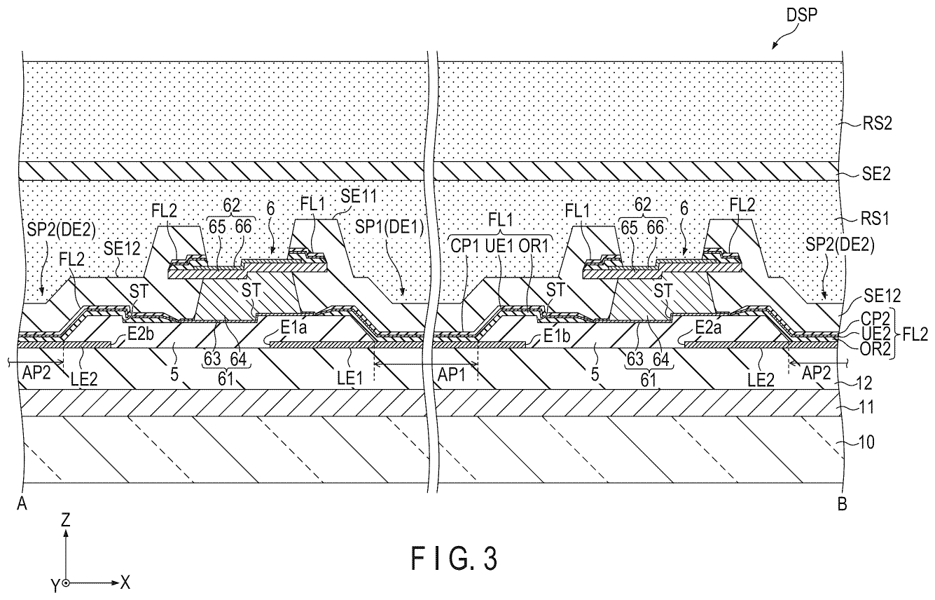

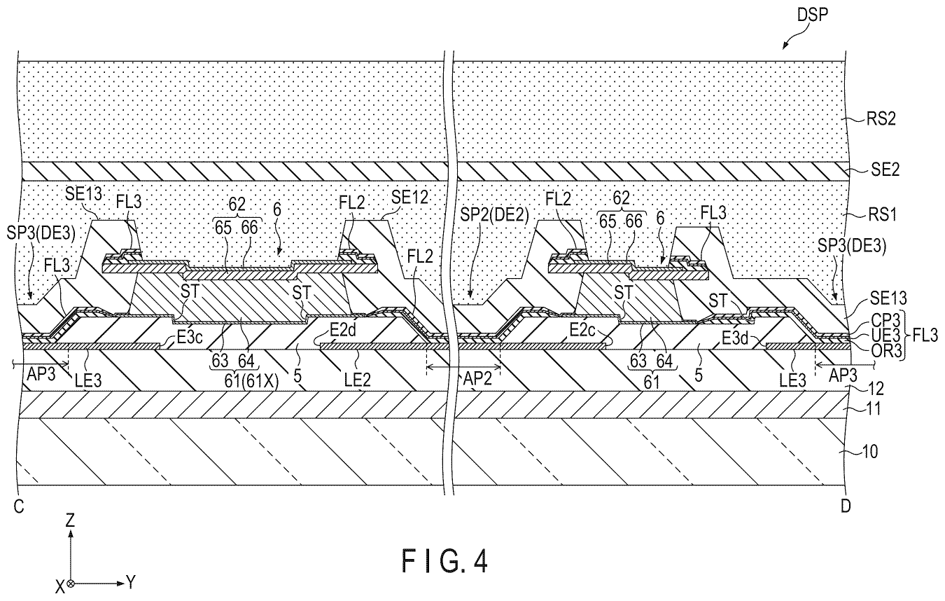

FIG. 3 is a schematic cross-sectional view of the display device DSP along the A-B line of FIG. 2. FIG. 4 is a schematic cross-sectional view of the display device DSP along the C-D line of FIG. 2.

As shown in FIG. 3 and FIG. 4, a circuit layer 11 is provided on the substrate 10 described above. The circuit layer 11 includes various circuits and lines such as the pixel circuits 1, scanning lines GL, signal lines SL and power lines PL shown in FIG. 1.

The circuit layer 11 is covered with an organic insulating layer 12. The organic insulating layer 12 functions as a planarization film which planarizes the irregularities formed by the circuit layer 11. The contact holes CH1, CH2 and CH3 shown in FIG. 2 are provided in the organic insulating layer 12.

The lower electrodes LE1, LE2 and LE3 are provided on the organic insulating layer 12. The rib layer 5 is provided on the organic insulating layer 12 and the lower electrodes LE1, LE2 and LE3. The end portions of the lower electrodes LE1, LE2 and LE3 are covered with the rib layer 5.

The partition 6 includes a conductive lower portion 61 provided on the rib layer 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom layer 63 and a stem layer 64. The bottom layer 63 is located between the stem layer 64 and the rib layer 5 and is formed so as to be thinner than the stem layer 64. For example, the both end portions of the bottom layer 63 protrude from the side surfaces of the stem layer 64.

Further, in the example of FIG. 3, the upper portion 62 has a first top layer 65 and a second top layer 66. The first top layer 65 is provided on the stem layer 64. The second top layer 66 is provided on the first top layer 65. The second top layer 66 may be formed so as to be thinner than the first top layer 65 as shown in the figure. The second top layer 66 may have a width which is less than that of the first top layer 65.

As shown in FIG. 3, a stacked film FL1 and a sealing layer SE11 are provided in subpixel SP1, and a stacked film FL2 and a sealing layer SE12 are provided in subpixel SP2. As shown in FIG. 4, a stacked film FL3 and a sealing layer SE13 are provided in subpixel SP3.

The stacked film FL1 includes an organic layer OR1, an upper electrode UE1 and a cap layer CP1. The stacked film FL2 includes an organic layer OR2, an upper electrode UE2 and a cap layer CP2. The stacked film FL3 includes an organic layer OR3, an upper electrode UE3 and a cap layer CP3.

The organic layer OR1 covers the rib layer 5 and is in contact with the lower electrode LE1 through the pixel aperture AP1. The organic layer OR2 covers the rib layer 5 and is in contact with the lower electrode LE2 through the pixel aperture AP2. The organic layer OR3 covers the rib layer 5 and is in contact with the lower electrode LE3 through the pixel aperture AP3.

The upper electrodes UE1, UE2 and UE3 cover the organic layers OR1, OR2 and OR3, respectively. Each of the upper electrodes UE1, UE2 and UE3 is in contact with at least one of the bottom layer 63 and stem layer 64 of the partition 6. The cap layers CP1, CP2 and CP3 cover the upper electrodes UE1, UE2 and UE3, respectively.

Of the lower electrode LE1 and the stacked film FL1, the portions which overlap the pixel aperture AP1 constitute the display element DE1 of subpixel SP1. Of the lower electrode LE2 and the stacked film FL2, the portions which overlap the pixel aperture AP2 constitute the display element DE2 of subpixel SP2. Of the lower electrode LE3 and the stacked film FL3, the portions which overlap the pixel aperture AP3 constitute the display element DE3 of subpixel SP3. The stacked film FL1 is partly located on the upper portion 62. This portion is spaced apart from, of the stacked film FL1, the portion located around the partition 6 (in other words, the portion which constitutes the display element DE1). Similarly, the stacked film FL2 is partly located on the upper portion 62. This portion is spaced apart from, of the stacked film FL2, the portion located around the partition 6 (in other words, the portion which constitutes the display element DE2). Further, the stacked film FL3 is partly located on the upper portion 62. This portion is spaced apart from, of the stacked film FL3, the portion located around the partition 6 (in other words, the portion which constitutes the display element DE3).

The sealing layers SE11, SE12 and SE13 are formed so as to be thicker than the stacked films FL1, FL2 and FL3. The sealing layers SE11, SE12 and SE13 continuously cover the respective stacked films FL1, FL2 and FL3 and the side portions of the partition 6 without being divided by the partition 6.

In the example of FIG. 3, the stacked film FL1 and sealing layer SE11 located on the partition 6 between subpixels SP1 and SP2 are spaced apart from the stacked film FL2 and sealing layer SE12 located on this partition 6. In the example of FIG. 4, the stacked film FL2 and sealing layer SE12 located on the partition 6 between subpixels SP2 and SP3 are spaced apart from the stacked film FL3 and sealing layer SE13 located on this partition 6.

As shown in FIG. 3 and FIG. 4, the sealing layers SE11, SE12 and SE13 are covered with a resin layer RS1. The resin layer RS1 is covered with a sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film or a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as polyimide. Each of the rib layer 5 and the sealing layers SE11, SE12, SE13 and SE2 is formed of an inorganic insulating material such as silicon nitride (SiNx), silicon oxide (SiOx) or silicon oxynitride (SiON). For example, the rib layer 5 is formed of silicon oxynitride, and each of the sealing layers SE11, SE12, SE13 and SE2 is formed of silicon nitride. Each of the resin layers RS1 and RS2 is formed of, for example, a resinous material (organic insulating material) such as epoxy resin or acrylic resin.

Each of the lower electrodes LE1, LE2 and LE3 has a reflective layer, and a pair of conductive oxide layers covering the upper and lower surfaces of the reflective layer. The reflective layer can be formed of, for example, a metal material having excellent light reflectivity, such as silver. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

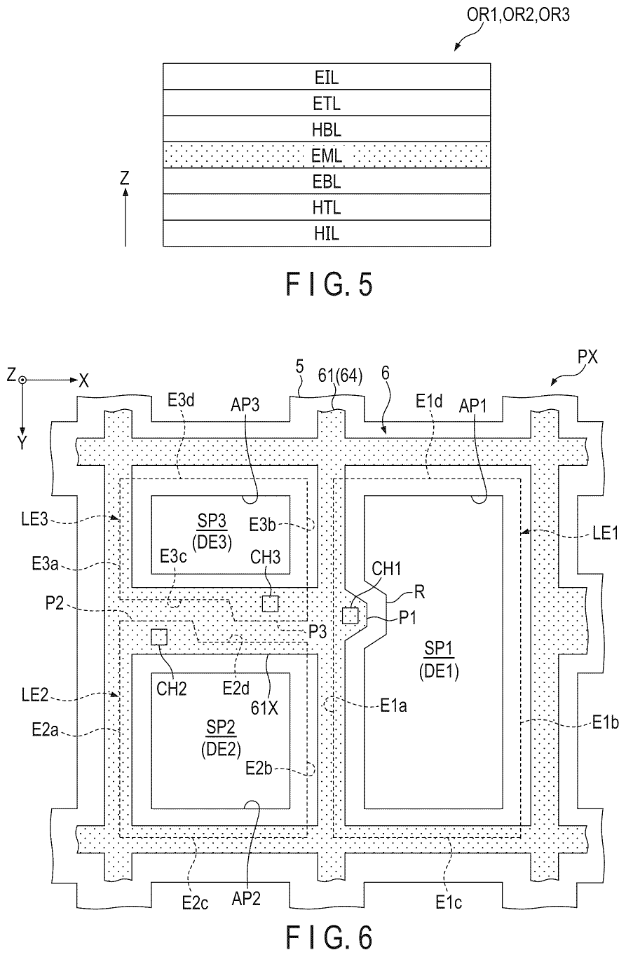

FIG. 5 is a diagram showing an example of a layer structure which could be applied to the organic layers OR1, OR2 and OR3. Each of the organic layers OR1, OR2 and OR3 consists of a plurality of thin films including a light emitting layer EML. This embodiment assumes a case where each of the organic layers OR1, OR2 and OR3 comprises a structure in which a hole injection layer HIL, a hole transport layer HTL, an electron blocking layer EBL, a light emitting layer EML, a hole blocking layer HBL, an electron transport layer ETL and an electron injection layer EIL are stacked in order in a Z-direction. It should be noted that each of the organic layers OR1, OR2 and OR3 may comprise another structure such as a tandem structure including a plurality of light emitting layers EML.

Each of the cap layers CP1, CP2 and CP3 comprises, for example, a multilayer structure in which a plurality of transparent layers are stacked. These transparent layers could include a layer formed of an inorganic material and a layer formed of an organic material. The transparent layers have refractive indices different from each other. For example, the refractive indices of these transparent layers are different from the refractive indices of the upper electrodes UE1, UE2 and UE3 and the refractive indices of the sealing layers SE11, SE12 and SE13. The cap layers CP1, CP2 and CP3 function as optical adjustment layers which improve the extraction efficiency of the light emitted from the organic layers OR1, OR2 and OR3, respectively. It should be noted that at least one of the cap layers CP1, CP2 and CP3 may be omitted.

The bottom layer 63 and stem layer 64 of the partition 6 are formed of, for example, metal materials different from each other. For the metal material of the bottom layer 63, for example, molybdenum (Mo), titanium (Ti), titanium nitride (TiN), a molybdenum-tungsten alloy (MoW) or a molybdenum-niobium alloy (MoNb) can be used. For the metal material of the stem layer 64, for example, aluminum (Al), an aluminum-neodymium alloy (AlNd), an aluminum-yttrium alloy (AlY) or an aluminum-silicon alloy (AlSi) can be used. It should be noted that at least one of the bottom layer 63 and the stem layer 64 may comprise a multilayer structure consisting of a plurality of layers. The stem layer 64 may include a layer formed of an insulating material.

For example, the first top layer 65 of the partition 6 is formed of a metal material, and the second top layer 66 is formed of a transparent conductive oxide. For the metal material of the first top layer 65, for example, titanium, titanium nitride, molybdenum, tungsten, a molybdenum-tungsten alloy or a molybdenum-niobium alloy can be used. For the conductive oxide of the second top layer 66, for example, ITO or IZO may be used. It should be noted that the upper portion 62 may comprise a single-layer structure formed of a specific material. The upper portion 62 may further include a layer formed of an insulating material.

Common voltage is applied to the partition 6. This common voltage is applied to each of the upper electrodes UE1, UE2 and UE3 which are in contact with the lower portions 61. The partition 6 functions as lines which apply common voltage to the upper electrodes UE1, UE2 and UE3. Pixel voltage is applied to the lower electrodes LE1, LE2 and LE3 through the pixel circuits 1 provided in subpixels SP1, SP2 and SP3, respectively, based on the video signals of the signal lines SL.

The organic layers OR1, OR2 and OR3 emit light based on the application of voltage.

Specifically, when a potential difference is formed between the lower electrode LE1 and the upper electrode UE1, the light emitting layer EML of the organic layer OR1 emits light in a blue wavelength range. When a potential difference is formed between the lower electrode LE2 and the upper electrode UE2, the light emitting layer EML of the organic layer OR2 emits light in a green wavelength range. When a potential difference is formed between the lower electrode LE3 and the upper electrode UE3, the light emitting layer EML of the organic layer OR3 emits light in a red wavelength range.

As another example, the light emitting layers EML of the organic layers OR1, OR2 and OR3 may emit light exhibiting the same color (for example, white). In this case, the display device DSP may comprise color filters which convert the light emitted from the light emitting layers EML into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers EML.

FIG. 6 is a schematic enlarged plan view of subpixels SP1, SP2 and SP3 shown in FIG. 2. These subpixels SP1, SP2 and SP3 constitute each pixel PX described above. Hereinafter, this specification explains the details of the shapes of the rib layer 5, the partition 6 and the lower electrodes LE1, LE2 and LE3 with reference to FIG. 4 to FIG. 6.

As shown in FIG. 6, the lower electrode LE1 has end portions Ela, E1b, E1c and E1d. The lower electrode LE2 has end portions E2a, E2b, E2c and E2d. The lower electrode LE3 has end portions E3a, E3b, E3c and E3d. The end portions Ela, E1b, E2a, E2b, E3a and E3b extend parallel to the Y-direction. The end portions E1c, E1d, E2c, E2d, E3c and E3d extend parallel to the X-direction. All of the end portions are covered with the rib layer 5.

The partition 6 (dotted portions) shown in FIG. 6 corresponds to the shape of the lower portion 61, more specifically, the shape of the stem layer 64. The lower portion 61 has substantially the same width as a whole. However, in the lower portion 61, a part 61X which extends in the X-direction between subpixels SP2 and SP3 has a width which is greater than that of the other portion.

In this embodiment, a part (first end portion) of the end portion of each of the lower electrodes LE1, LE2 and LE3 overlaps the stem layer 64, and the other part (second end portion) does not overlap the stem layer 64. Here, the expression “the end portion of each of the lower electrodes LE1, LE2 and LE3 overlaps the lower portion 61” means that these end portions are located under the lower portion 61.

Specifically, the end portions Ela and E1c of the lower electrode LE1 overlap the lower portion 61, and neither the end portion E1b nor the end portion E1d overlaps the lower portion 61. The end portions E2a, E2c and E2d of the lower electrode LE2 overlap the lower portion 61, and the end portion E2b does not overlap the lower portion 61. The end portions E3a and E3c of the lower electrode LE3 overlap the lower portion 61, and neither the end portion E3b nor the end portion E3d overlaps the lower portion 61.

For example, when the lower electrodes LE1 and LE2 and the lower portion 61 between them are particularly looked at, one of the end portions of the lower electrodes LE1 and LE2 overlaps this lower portion 61, and the other one does not overlap this lower portion 61. This relationship in which the lower portion 61 overlaps the end portion (first end portion) of one of adjacent lower electrodes and does not overlap the end portion (second end portion) of the other one is established in a large part of the lower portion 61. However, the part 61X overlaps both the end portion E2d of the lower electrode LE2 and the end portion E3c of the lower electrode LE3.

In the example of FIG. 6, the partition 6 (lower portion 61) which overlaps the end portion Ela has a protrusion portion P1 which protrudes toward the pixel aperture AP1. The pixel aperture AP1 has a recess portion R which has a concave shape corresponding to the protrusion portion P1. The contact hole CH1 is located between the end portion Ela and the pixel aperture AP1 and overlaps the protrusion portion P1.

The end portion E2d of the lower electrode LE2 has a protrusion portion P2 which protrudes toward the lower electrode LE3. The end portion E3c of the lower electrode LE3 has a protrusion portion P3 which protrudes towards the lower electrode LE2. Both of these protrusion portions P2 and P3 overlap the part 61X. The contact hole CH2 overlaps the protrusion portion P2 and the part 61x. The contact hole CH3 overlaps the protrusion portion P3 and the part 61x.

It should be noted that the location of the contact hole CH1, CH2 or CH3 is not limited to the example of FIG. 6. For example, the contact hole CH1 may be provided between the end portion E1c and the pixel aperture AP1. In this case, the partition 6 which overlaps the end portion E1c may have the protrusion portion P1.

As shown in FIG. 3 and FIG. 4, stepped portions ST are generated on the upper surface of the rib layer 5 based on the end portions of the lower electrodes LE1, LE2 and LE3. For example, a stepped portion (first stepped portion) ST generated by each end portion which is located under the partition 6, such as the end portions Ela E2a, E2c, E2d and E3c shown in FIG. 3 and FIG. 4, is covered with the bottom layer 63 and the stem layer 64. The upper surface of each of the stem layer 64, the first top layer 65 and the second top layer 66 may be deformed based on the stepped portions ST.

To the contrary, for example, a stepped portion (second stepped portion) ST generated by each end portion which is not located under the partition 6, such as the end portions E1b, E2b and E3d shown in FIG. 3 and FIG. 4, is not covered with the bottom layer 63 or the stem layer 64. The stacked films FL1, FL2 and FL3 could be deformed based on these stepped portions ST.

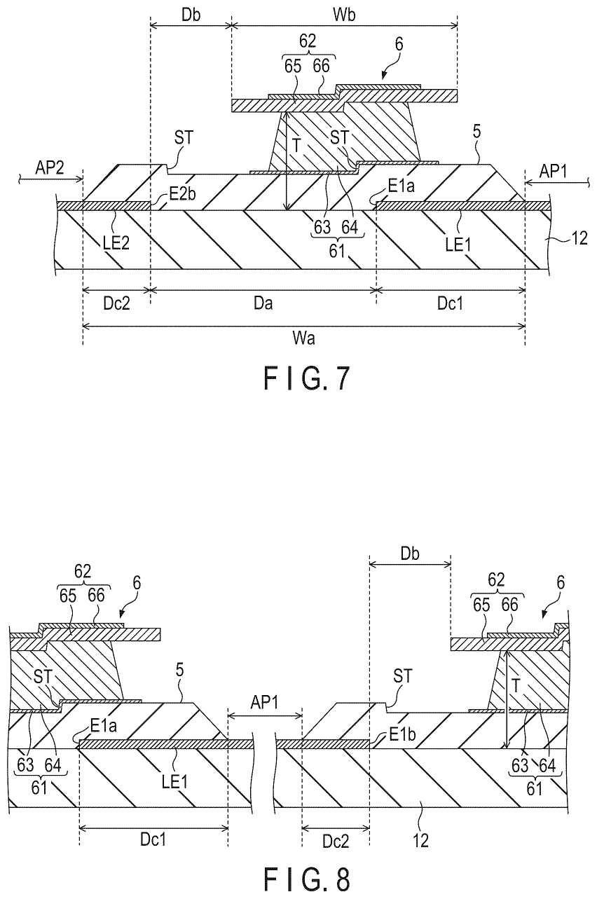

FIG. 7 is a schematic enlarged cross-sectional view of the lower electrodes LE1 and LE2, rib layer 5 and partition 6 shown on the left side of FIG. 3. Now, this specification explains the details of a configuration which can be applied to a pair of adjacent lower electrodes, the rib layer 5 which overlaps the pair of lower electrodes, and the partition 6 which overlaps the end portion of one of the pair of lower electrodes, using FIG. 7 as a representative figure.

The rib layer 5 shown in FIG. 7 has width Wa. The partition 6 has width Wb which is less than width Wa (Wa>Wb). Width Wa corresponds to the distance between the pixel apertures AP1 and AP2. Width Wb corresponds to the width of the upper portion 62, more specifically, the width of the first top layer 65.

Distance Da between the lower electrodes LE1 and LE2 is less than width Wa (Da<Wa). Distance Da is, for example, equal to width Wb. For example, width Wa is 8 to 10 μm, and each of width Wb and distance Da is 4 to 5 μm.

The end portion E2b of the lower electrode LE2 and the upper portion 62 are spaced apart from each other as seen in plan view. Distance Db between the end portion E2b and the upper portion 62 in plan view is, for example, greater than or equal to ½ of total thickness T of the rib layer 5 and the lower portion 61 (the bottom layer 63 and the stem layer 64).

In this embodiment, distance (first distance) Dc1 between the end portion Ela and the pixel aperture AP1 in plan view is greater than distance (second distance) Dc2 between the end portion E2b and the pixel aperture AP2 in plan view (Dc1>Dc2). Distance Dc1 corresponds to the width of the area in which the lower electrode LE1 is covered with the rib layer 5 in FIG. 7. Distance Dc2 corresponds to the width of the area in which the lower electrode LE2 is covered with the rib layer 5 in FIG. 7.

The structure shown in FIG. 7 can be also applied to the structure of the vicinity of the adjacent lower electrodes LE1 and LE3, the structure of the vicinity of the adjacent lower electrodes LE2 and LE3 and the structure of the vicinity of the adjacent two lower electrodes LE1. However, the structure of the vicinity of the part 61X shown in FIG. 6 is as shown on the left side of FIG. 4 and is different from that of FIG. 7.

FIG. 8 is a schematic enlarged cross-sectional view of the vicinity of the end portions Ela and E1b of the lower electrode LE1 shown in FIG. 3. In FIG. 7, the end portions of adjacent two lower electrodes are particularly looked at to explain the structure. This structure is also seen in a case where the end portions of one lower electrode are particularly looked at as shown in the example of FIG. 8.

Specifically, in the example of FIG. 8, the end portion E1b of the lower electrode LE1 and the upper portion 62 are spaced apart from each other as seen in plan view. Distance Db between the end portion E1b and the upper portion 62 in plan view is, for example, greater than or equal to ½ of total thickness T of the rib layer 5 and the lower portion 61. Distance Dc1 between the end portion Ela and the pixel aperture AP1 is greater than distance Dc2 between the end portion E1b and the pixel aperture AP1 (Dc1>Dc2).

For example, the structures of the end portions E1c and E1d of the lower electrode LE1, the end portions E2a and E2b of the lower electrode LE2, the end portions E3a and E3b of the lower electrode LE3 and further the end portions E3c and E3d of the lower electrode LE3 are similar to the structure shown in FIG. 8.

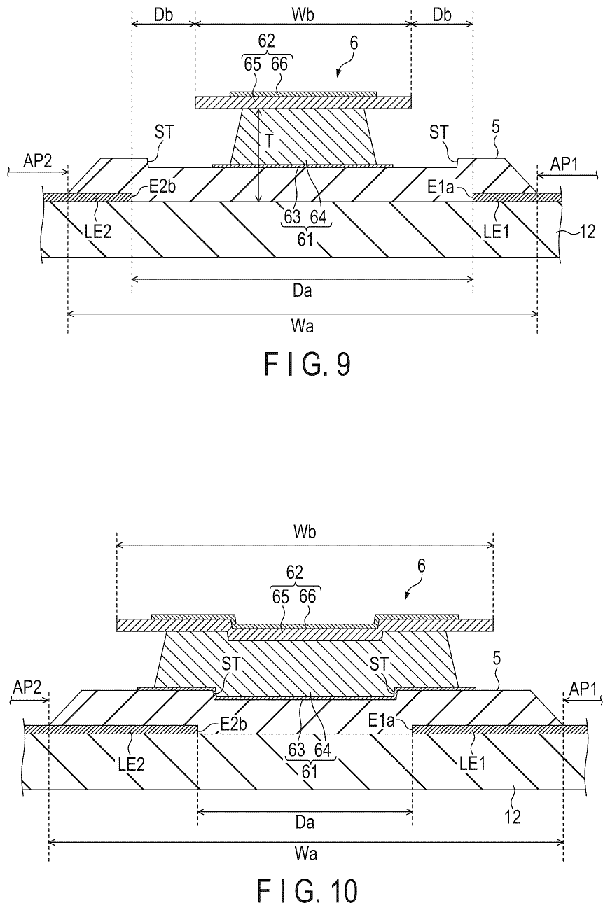

FIG. 9 and FIG. 10 are schematic cross-sectional views of the configurations of comparative examples. These figures focus attention on the end portions Ela and E2b of the lower electrodes LE1 and LE2, the rib layer 5 and the partition 6 in a manner similar to that of FIG. 7.

In FIG. 9, neither the end portion Ela of the lower electrode LE1 nor the end portion E2b of the lower electrode LE2 is located under the partition 6. By this configuration, stepped portions ST caused by these end portions Ela and E2b are exposed from the lower portion 61.

When the partition 6 is formed, the layers to be processed into the bottom layer 63, the stem layer 64, the first top layer 65 and the second top layer 66 are formed in the entire display area DA. These layers could be deformed based on the stepped portions ST. If the stepped portions ST are close to the lower portion 61 in the design, the end portions of the upper portion 62 (the first top layer 65 and the second top layer 66) protruding from the lower portion 61 could include a portion which is deformed by the effect of the stepped portions ST. Specifically, there is a possibility that the end portions of the upper portion 62 warp to the upper side.

The layers constituting the stacked films FL1, FL2 and FL3 are formed in the entire display area DA by vapor deposition. At the time of the vapor deposition, these layers are divided by the partition 6 having an overhang shape. If the end portions of the upper portion 62 warp to the upper side, for example, there is a possibility that the organic layers OR1, OR2 and OR3 are attached to a wide range of the lower portion 61, thereby blocking the contact between the upper electrodes UE1, UE2 and UE3 which are formed later and the lower portion 61.

Therefore, in the configuration of FIG. 9, the end portions Ela and E2b of the lower electrodes LE1 and LE2 need to be sufficiently spaced apart from the partition 6. For example, when distance Db between the upper portion 62 and each of the end portions Ela and E2b in plan view is greater than or equal to ½ of total thickness T of the rib layer 5 and the lower portion 61 (Db>T/2) as described above, the shape defect of the end portions of the upper portion 62 can be prevented.

It should be noted that, in the configuration of FIG. 9, distance Db should be assured on the both sides of the partition 6. Thus, width Wa of the rib layer 5 is also increased. For example, when width Wb of the partition 6 is 4 to 5 μm, width Wa of the rib layer 5 must be 10 to 12 μm in the configuration of FIG. 9. When width Wa of the rib layer 5 is increased in this manner, the pixel apertures AP1, AP2 and AP3 become small in accordance with the increase in width Wa, and thus, the aperture ratios of subpixels SP1, SP2 and SP3 are decreased.

In FIG. 10, both the end portion Ela of the lower electrode LE1 and the end portion E2b of the lower electrode LE2 are located under the lower portion 61. By this configuration, both of the stepped portions ST caused by the end portions Ela and E2b are covered with the lower portion 61. In this case, the shape defect of the end portions of the upper portion 62 caused by the stepped portions ST can be prevented. It is difficult to make distance Da between the lower electrodes LE1, LE2 and LE3 less than, for example, 4 to 5 μm. Therefore, width Wb of the partition 6 needs to be increased in the configuration of FIG. 10.

In addition, in the vicinity of the partition 6, the evaporation materials emitted from evaporation sources are blocked by the upper portion 62. Thus, the thicknesses of the stacked films FL1, FL2 and FL3 are decreased. Therefore, to form the stacked films FL1, FL2 and FL3 so as to have satisfactory thicknesses in the pixel apertures AP1, AP2 and AP3, the partition 6 needs to be spaced apart from the pixel apertures AP1, AP2 and AP3 to some extent. In consideration of this margin, a width of 10 to 12 μm is required as width Wa of the rib layer 5 in the example of FIG. 10 as well.

With respect to these comparative examples, the configuration of the embodiment shown in FIG. 7 can decrease width Wa of the rib layer 5 even while preventing the shape defect of the upper portion 62 and increase the aperture ratios of subpixels SP1, SP2 and SP3. In this manner, the yield of the display device DSP can be improved, and the display quality can be also improved.

Specifically, in the configuration of FIG. 7, the stepped portion ST caused by the end portion Ela of the lower electrode LE1 is covered with the lower portion 61. Thus, the shape defect caused to the upper portion 62 by the stepped portion ST is prevented. In addition, the shape defect caused to the upper portion 62 by the stepped portion ST generated by the end portion E2b of the lower electrode LE2 can be prevented by making distance Db greater than or equal to ½ of total thickness T.

Further, since distance Db is assured in the configuration of FIG. 7, even if distance Dc2 between the end portion E2b and the pixel aperture AP2 is made less, the stacked film FL2 having a satisfactory thickness can be formed in the pixel aperture AP2. By this configuration, width Wa of the rib layer 5 can be reduced compared to the comparative examples of FIG. 9 and FIG. 10.

Here, this specification explains the effects obtained from the embodiment while focusing attention on the structure of the vicinity of the end portions of the adjacent lower electrodes LE1 and LE2 as shown in FIG. 7, FIG. 9 and FIG. 10. However, similar effects can be obtained based on the structure of the vicinity of the adjacent lower electrodes LE1 and LE3, the structure of the vicinity of the end portions of the adjacent lower electrodes LE2 and LE3 and the structure of the vicinity of the end portions of the adjacent two lower electrodes LE1.

This specification explains second to sixth embodiments below. Regarding the display device DSP, configurations which are not referred to in each embodiment are the same as the first embodiment.

### Second Embodiment

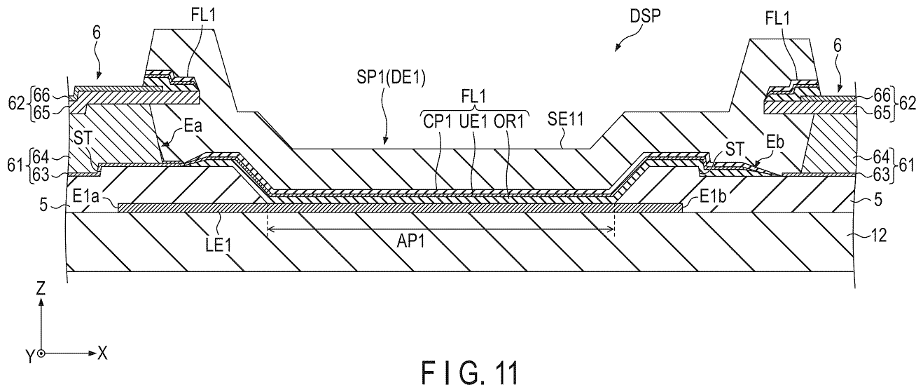

FIG. 11 is a schematic cross-sectional view of a display device DSP according to the second embodiment. The section shown here corresponds to a section obtained by cutting subpixel SP1 shown in FIG. 2 and FIG. 3 in an X-direction. In this figure, a substrate 10, a circuit layer 11, resin layers RS1 and RS2 and a sealing layer SE2 are omitted.

In a manner similar to that of the first embodiment, an end portion (first end portion) Ela of a lower electrode LE1 is located under the lower portion 61 of a partition 6, and an end portion (second end portion) E1b is spaced apart from the partition 6 in the X-direction. In this configuration, a stepped portion ST generated in a rib layer 5 by the end portion Ela is covered with the lower portion 61. To the contrary, a stepped portion ST generated by the end portion E1b is exposed from the lower portion 61.

An upper electrode UE1 has end portions Ea and Eb in the X-direction. The end portion (third end portion) Ea is located on the end portion Ela side of the lower electrode LE1. The end portion (fourth end portion) Eb is located on the end portion E1b side of the lower electrode LE1.

In the example of FIG. 11, the end portion Ea is in contact with the lower portion 61 (a bottom layer 63 and a stem layer 64). The end portion Eb is spaced apart from the lower portion 61. This configuration can be realized by, for example, inclining the evaporation source of the upper electrode UE1 with respect to a Z-direction. By inclining the evaporation source, the upper electrode UE1 can be formed such that at least the end portion Ea is satisfactorily in contact with the lower portion 61.

It should be noted that there is a possibility that the upper electrode UE1 is divided by the stepped portion ST generated by the end portion E1b since the upper electrode UE1 is thin. To the contrary, the stepped portion ST generated by the end portion Ela is covered with the lower portion 61. This configuration can prevent the division of the upper electrode UE1 to be caused by this stepped portion ST, thereby satisfactorily electrically connecting the lower portion 61 to the upper electrode UE1.

The structure of subpixel SP1 is explained above. However, similar structures can be applied to subpixels SP2 and SP3. Specifically, each of upper electrodes UE2 and UE3 may have an end portion which is in contact with the lower portion 61 and an end portion which is spaced apart from the lower portion 61. For example, the upper electrodes UE1 and UE2 are in contact with at least the part 61X shown in FIG. 6.

### Third Embodiment

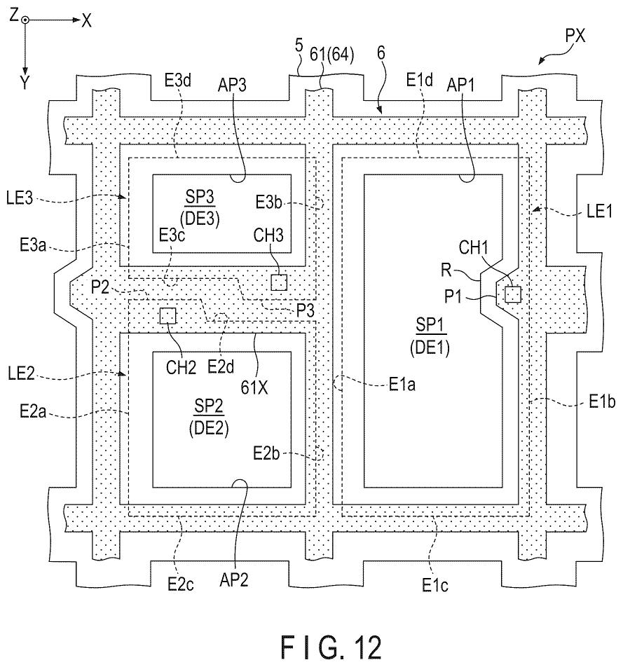

FIG. 12 is a schematic enlarged plan view of subpixels SP1, SP2 and SP3 according to the third embodiment. In the example of FIG. 12, end portions E1b and E1c of a lower electrode LE1, end portions E2b, E2c and E2d of a lower electrode LE2 and end portions E3b and E3c of a lower electrode LE3 overlap a lower portion 61. To the contrary, none of end portions Ela and E1d of the lower electrode LE1, an end portion E2a of the lower electrode LE2 and end portions E3a and E3d of the lower electrode LE3 overlaps the lower portion 61.

In the example of FIG. 12, a partition 6 (lower portion 61) which overlaps the end portion E1b has a protrusion portion P1 which protrudes toward a pixel aperture AP1. The pixel aperture AP1 has a recess portion R which has a concave shape corresponding to the protrusion portion P1. A contact hole CH1 is located between the end portion E1b and the pixel aperture AP1 and overlaps the protrusion portion P1.

### Fourth Embodiment

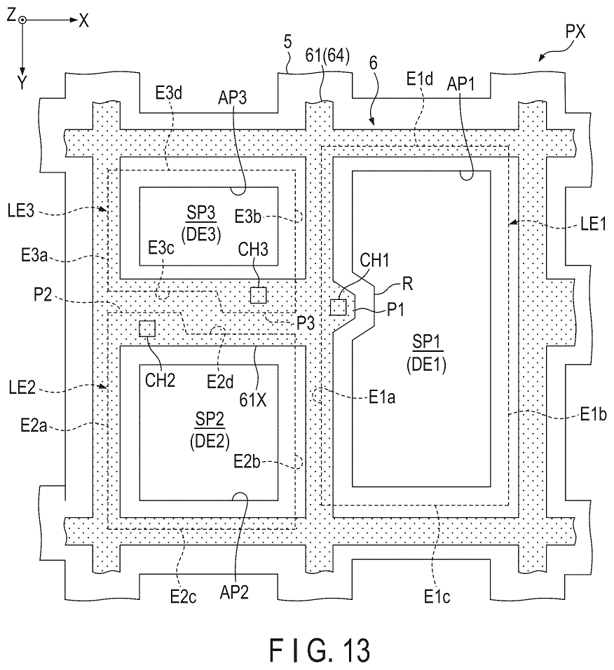

FIG. 13 is a schematic enlarged plan view of subpixels SP1, SP2 and SP3 according to the fourth embodiment. In the example of FIG. 13, end portions Ela and E1d of a lower electrode LE1, end portions E2a, E2c and E2d of a lower electrode LE2 and end portions E3a and E3c of a lower electrode LE3 overlap a lower portion 61. To the contrary, none of end portions E1b and E1c of the lower electrode LE1, an end portion E2b of the lower electrode LE2 and end portions E3b and E3d of the lower electrode LE3 overlaps the lower portion 61.

### Fifth Embodiment

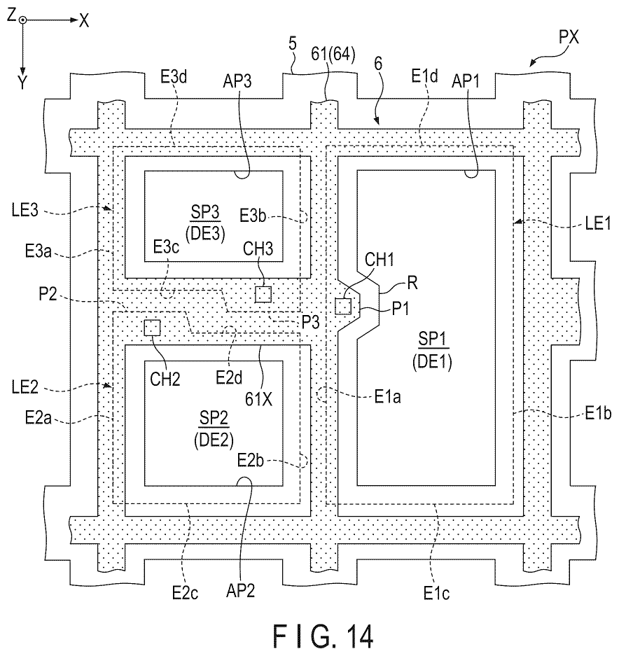

FIG. 14 is a schematic enlarged plan view of subpixels SP1, SP2 and SP3 according to the fifth embodiment. In the example of FIG. 14, end portions Ela and E1d of a lower electrode LE1, end portions E2a and E2d of a lower electrode LE2 and end portions E3a, E3c and E3d of a lower electrode LE3 overlap a lower portion 61. To the contrary, none of end portions E1b and E1c of the lower electrode LE1, end portions E2b and E2c of the lower electrode LE2 and an end portion E3b of the lower electrode LE3 overlaps the lower portion 61.

### Sixth Embodiment

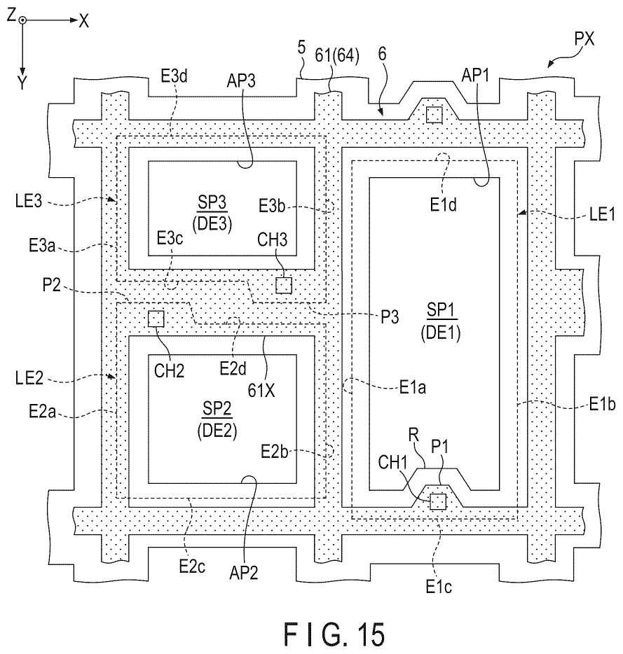

FIG. 15 is a schematic enlarged plan view of subpixels SP1, SP2 and SP3 according to the fifth embodiment. In the example of FIG. 15, an end portion E1c of a lower electrode LE1, end portions E2a, E2b and E2d of a lower electrode LE2 and end portions E3a, E3b, E3c and E3d of a lower electrode LE3 overlap a lower portion 61. Thus, in the example of FIG. 15, the whole circumference of the lower electrode LE3 overlaps the lower portion 61. However, none of end portions Ela, E1b and E1d of the lower electrode LE1 and an end portion E2c of the lower electrode LE2 overlaps the lower portion 61.

The configurations of the third to sixth embodiments described above also allow the attainment of a configuration in which one of the end portions of adjacent lower electrodes overlaps the lower portion 61, and the other one does not overlap the lower portion 61, excluding the end portions E2d and E3c. Thus, effects similar to those of the first embodiment can be obtained. In the third to sixth embodiments, similarly, the configuration explained using FIG. 7 can be applied to the end portions of adjacent two lower electrodes, the rib layer 5 which covers these end portions and the lower portion 61 located on the rib layer 5.

It should be noted that the locational relationships of the end portions of the lower electrodes LE1, LE2 and LE3 and the lower portion 61 are not limited to the example shown in each embodiment. For example, in each embodiment, the end portion E2d of the lower electrode LE2 and the end portion E3c of the lower electrode LE3 overlap the lower portion 61 (part 61X). However, at least one of the end portions E2d and E3c may not overlap the lower portion 61.

All of the display devices that can be implemented by a person of ordinary skill in the art through arbitrary design changes to the display device disclosed as each embodiment described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a first lower electrode having a first end portion;
a second lower electrode having a second end portion spaced apart from the first end portion;
a rib layer which has a first pixel aperture overlapping the first lower electrode and a second pixel aperture overlapping the second lower electrode, and covers the first end portion and the second end portion;
a partition which includes a lower portion located between the first pixel aperture and the second pixel aperture and provided above the rib layer, and an upper portion having an end portion protruding from a side surface of the lower portion;
a first organic layer which is in contact with the first lower electrode through the first pixel aperture and emits light based on application of voltage; and
a second organic layer which is in contact with the second lower electrode through the second pixel aperture and emits light based on application of voltage;
a first upper electrode which covers the first organic layer; and
a second upper electrode which covers the second organic layer, wherein
the first end portion overlaps the lower portion in plan view, and
the second end portion does not overlap the lower portion in plan view.

2. The display device of claim 1, wherein
the second end portion and the upper portion are spaced apart from each other in plan view.

3. The display device of claim 2, wherein
a distance between the second end portion and the upper portion in plan view is greater than or equal to ½ of a total thickness of the rib layer and the lower portion.

4. The display device of claim 1, wherein
an upper surface of the rib layer has a first stepped portion generated by the first end portion, and
the lower portion covers the first stepped portion.

5. The display device of claim 4, wherein
the upper surface of the rib layer has a second stepped portion generated by the second end portion, and
the lower portion does not cover the second stepped portion.

6. The display device of claim 1, wherein
a first distance between the first end portion and the first pixel aperture in plan view is greater than a second distance between the second end portion and the second pixel aperture in plan view.

7. The display device of claim 1, further comprising:
a pixel circuit provided under the first lower electrode; and
an organic insulating layer provided between the first lower electrode and the pixel circuit, wherein
the first lower electrode is connected to the pixel circuit through a contact hole provided in the organic insulating layer, and
the contact hole is located between the first end portion and the first pixel aperture in plan view.

8. The display device of claim 7, wherein
the partition has a protrusion portion which protrudes toward the first pixel aperture in plan view, and
the contact hole overlaps the protrusion portion in plan view.

9. The display device of claim 1, wherein
the lower portion includes:
a stem layer formed of a metal material; and
a bottom layer which is formed of a metal material different from the stem layer and which is located between the stem layer and the rib layer.

10. The display device of claim 1, wherein
the upper portion includes:
a first top layer formed of a metal material; and
a second top layer formed of a transparent conductive oxide and provided on the first top layer.

11. A display device comprising:
a lower electrode having a first end portion and a second end portion;
a rib layer which has a pixel aperture overlapping the lower electrode and covers the first end portion and the second end portion;
a partition which includes a lower portion provided above the rib layer and an upper portion having an end portion protruding from a side surface of the lower portion, and surrounds the pixel aperture;
an organic layer which is in contact with the lower electrode through the pixel aperture, and emits light based on application of voltage; and
an upper electrode which covers the organic layer, wherein
the first end portion overlaps the lower portion in plan view, and
the second end portion does not overlap the lower portion in plan view.

12. The display device of claim 11, wherein
the second end portion and the upper portion are spaced apart from each other in plan view.

13. The display device of claim 12, wherein
a distance between the second end portion and the upper portion in plan view is greater than or equal to ½ of a total thickness of the rib layer and the lower portion.

14. The display device of claim 11, wherein
an upper surface of the rib layer has a first stepped portion generated by the first end portion, and
the lower portion covers the first stepped portion.

15. The display device of claim 14, wherein
the upper surface of the rib layer has a second stepped portion generated by the second end portion, and
the lower portion does not overlap the second stepped portion.

16. The display device of claim 11, wherein
a first distance between the first end portion and the pixel aperture in plan view is greater than a second distance between the second end portion and the pixel aperture in plan view.

17. The display device of claim 11, further comprising:
a pixel circuit provided under the lower electrode; and
an organic insulating layer provided between the lower electrode and the pixel circuit, wherein
the lower electrode is connected to the pixel circuit through a contact hole provided in the organic insulating layer, and
the contact hole is located between the first end portion and the pixel aperture in plan view.

18. The display device of claim 17, wherein
the partition has a protrusion portion which protrudes toward the pixel aperture in plan view, and
the contact hole overlaps the protrusion portion in plan view.

19. The display device of claim 11, wherein
the upper electrode has a third end portion on the first end portion side, and a fourth end portion on the second end portion side,
the third end portion is in contact with the lower portion, and
the fourth end portion is spaced apart from the lower portion.

20. The display device of claim 11, wherein
the lower portion includes:
a stem layer formed of a metal material; and
a bottom layer which is formed of a metal material different from the stem layer and which is located between the stem layer and the rib layer.
